(19) United States
(12) Patent Application Publication
(10) Pub. No.: US 2025/0372149 A1
(43) Pub. Date: Dec. 4, 2025

(54) APPARATUSES AND METHODS FOR INCREASING TIMING MARGINS FOR DECISION FEEDBACK EQUALIZATION

(71) Applicant: Micron Technology, Inc., Boise, ID (US)

(72) Inventors: Brian W. Huber, Allen, TX (US); Shingo Mitsubori, Tokyo (JP)

(73) Assignee: Micron Technology, Inc., Boise, ID (US)

(21) Appl. No.: 19/207,630

(22) Filed: May 14, 2025

Related U.S. Application Data
(60) Provisional application No. 63/654,612, filed on May 31, 2024.

(51) Int. Cl. G11C 11/4076; G11C 11/409

(52) U.S. Cl. CPC G11C 11/4076; G11C 11/409

(57) ABSTRACT

A decision feedback equalizer (DFE) circuit may selectively receive a gated data strobe (DQS) signal based on an external DQS signal. The DFE circuit may capture data to store in a buffer responsive to receiving the gated DQS signal. After a write operation, an additional gating event may occur responsive to one or more internal signals. This may effectively delay when the gated DQS signal is received by the DFE circuit. The gated DQS signal may not be received by the DFE circuit until after a reset of the DFE buffer.

### CROSS REFERENCE TO RELATED APPLICATION(S)

This application claims the benefit under 35 U.S.C. § 119 of the earlier filing date of U.S. Provisional Application Ser. No. 63/654,612 filed May 31, 2024 the entire contents of which is hereby incorporated by reference in its entirety for any purpose.

### BACKGROUND

High data reliability, high speed memory access, lower power consumption and reduced chip size are features that are demanded from semiconductor memory. Memory devices may utilize timing with phase shifts of data signals, data strobes, and/or other signals to perform operations (e.g., write operations). When write data is transmitted from a processor or controller via data terminals (DQ pads), there may be “reflections” of preceding bits at the DQ pads, which may interfere with proper interpretation of the current bit received at the DQ pads (e.g., unable to determine if a bit is ‘0’ or ‘1’). Reflections may be caused by various factors such as capacitance on conductive lines, impedance mismatch between the semiconductor memory and a physical interface (PHY) of a controller, electrical interference, and the like.

A decision feedback equalizer (DFE) circuit may be used to maintain a buffer of a number (e.g., four) of preceding data bits to improve accuracy in interpreting whether a current bit is high or low. The number of bits in the buffer may be referred to as “taps” (e.g., a 4-tap DFE). The DFE buffer may improve compensation for reflections at the data terminal (DQ) from the preceding data bit. For example, the preceding bits may be used to generate coefficients used in a summer of the DFE to adjust the level of a data bit as described in the JEDEC DDR5 Standard No. 79-5C, which incorporated herein by reference. However, depending on the design of the DFE circuitry, the preceding bits stored in the buffer may be used in other ways by the DFE to improve determination of data bits received by the memory.

### BRIEF DESCRIPTION OF THE DRAWINGS

FIG. 1 illustrates a schematic block diagram of a semiconductor device in accordance with an embodiment of the present disclosure.

FIG. 2 is a timing diagram illustrating various signals of a semiconductor device according to at least one embodiment of the disclosure.

FIG. 3 is a timing diagram illustrating various signals of a semiconductor device according to at least one embodiment of the disclosure.

FIG. 4 is a block diagram of circuitry included in a semiconductor device according to at least one embodiment of the disclosure.

FIG. 5 is a circuit diagram of a portion of a data path included in a semiconductor device according to at least one embodiment of the disclosure.

FIG. 6 is a circuit diagram of a portion of a data path included in a semiconductor device according to at least one embodiment of the disclosure.

FIG. 7 is a flow chart of a method according to at least one embodiment of the present disclosure.

### DETAILED DESCRIPTION

Certain details are set forth below to provide a sufficient understanding of embodiments of the disclosure. However, it will be clear to one having skill in the art that embodiments of the disclosure may be practiced without these particular details. Moreover, the particular embodiments of the present disclosure described herein are provided by way of example and should not be used to limit the scope of the disclosure to these particular embodiments.

Memory arrays may generally include a number of memory cells arranged at the intersection of word lines (rows) and bit lines/digit lines (columns). During a read operation, the memory may receive a read command and row and column addresses which indicate which memory cell(s) data should be read from. The data is provided to output buffers, and read off from data input/output (DQ) pads of the memory. During a write operation, the memory receives a write command and row and column addresses which indicate which memory cell(s) data should be written to. Responsive to the write command, the memory activates a number of input buffers, which allows data to be received from the DQ pads. Each DQ pad may be coupled to a set of input buffers, which may latch data received in series. For example, a first input buffer receives a first serial bit, a second input buffer receives a second serial bit, and so forth.

Each input buffer includes a latch which latches either a logical high or a logical low responsive to a write clock based on a voltage on the input terminal. The latch may have a threshold voltage, and if the voltage on the terminal is above the threshold then a logical high may be latched and if the voltage on the terminal is below the threshold then a logical low may be latched. The input buffers may include decision feedback equalizer (DFE) circuits which may set the threshold voltage based on a state of the previous serial bit or bits which was latched along that data terminal. For example, if the previous bit was a logical high, then the threshold may be set to a first threshold voltage, and if the previous bit was a logical low, then the threshold may be set to a second threshold voltage lower than the first threshold voltage. The degree to which the thresholds are adjusted by the DFE circuits may be an adjustable value for example set by a DFE code stored in a mode register of the memory.

To allow for higher data rates, certain memory devices, such as DDR memory devices may utilize data strobe signals, generally referred to as DQS signals. In some memory devices, the DQS signals may be provided as a differential pair of data strobe signals to provide differential pair signaling during reads and writes. The DQS signals are driven by the external processor or controller sending the data (e.g., for a write command) or by the memory device (e.g., for a read command). The frequency of the DQS signals may be the same or different than the frequency of a system clock (CLK) provided by the processor or controller. Data may be provided or received on the rising and falling edges of the DQS signal resulting in a 2× bit rate. For read commands, the DQS signals are effectively additional data output (DQ) signals with a predetermined pattern. For write commands, the DQS signals are used as clock signals to capture the corresponding input data. In some cases, the controller may drive the DQS signal before providing the first bit of data at the DQ pads (e.g., preamble) and continue to drive the DQS signal after the last bit of data has been provided at the DQ pads (e.g., postamble).

In some memory devices, the DQS signal is used to control, at least in part, when the DFE begins capturing data and storing it in the buffer. The internal DQS signal may be gated by additional circuitry to control when the internal DQS signal is passed to other components of a memory device to control when the DFE begins capturing data.

Between write operations, the buffer may be reset to an initial state (e.g., all high or low values). In some cases, for consecutive write operations, there may not be enough time to properly reset the buffer due, at least in part, to the timing of starting and/or stopping of driving the DQS signal between the consecutive write operations. Improper reset of the buffer may cause a phase change in the bits stored in the buffer, and/or incorrect information may be used to compensate for reflections, reducing reliability of analyzing the write data associated with the second write command by the DFE. Accordingly, improved timing margins for DFE circuitry is desired.

The present disclosure is directed to making a 1CLK DQS gap (e.g., the DQS signal is not driven for one cycle of the system clock) appear as a 2CLK DQS gap internally. In some embodiments, non-continuous external DQS signals (e.g., non-continuous driving of the DQS signal) between consecutive write commands (e.g., write-to-write) may allow for a signal gating event. The signal gating event may allow an internal preamble pulse erasure to occur. This may increase the timing margin for resetting the DFE buffer by a full clock cycle.

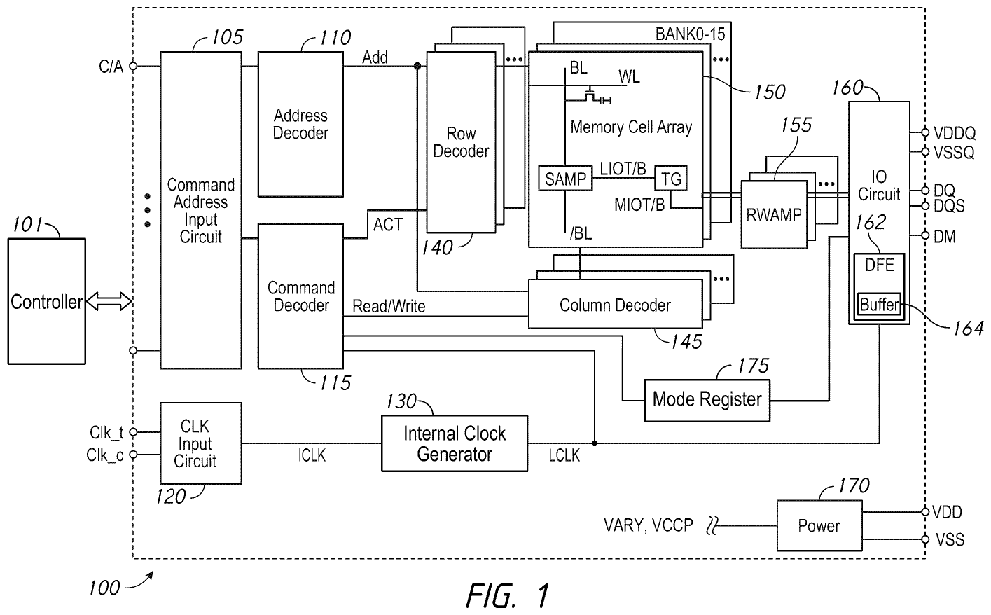

FIG. 1 illustrates a schematic block diagram of a semiconductor device in accordance with an embodiment of the present disclosure. The semiconductor device 100 includes a memory die. The memory die may include a command/address input circuit 105, an address decoder 110, a command decoder 115, a clock input circuit 120, internal clock generator 130, row decoder 140, column decoder 145, memory array 150, read/write amplifiers 155, I/O circuit 160, power circuit 170, and mode register 175.

In some embodiments, the semiconductor device 100 may include, without limitation, a dynamic random-access memory (DRAM) device, such as double data rate (DDR), low power DDR (LPDDR), or graphics DDR (GDDR), integrated into a single semiconductor chip, for example. The die may be mounted on an external substrate, for example, a memory module substrate, a mother board or the like. In some embodiments, semiconductor device 100 may be one of multiple semiconductor devices 100 (e.g., ×8 or ×16 devices) arranged on a dual inline memory module (DIMM). The devices may communicate with one or more controllers, such as controller 101.

The semiconductor device 100 may include a memory array 150. The memory array 150 includes a plurality of banks (BANK0-15), each bank including a plurality of word lines WL, a plurality of bit lines BL, and a plurality of memory cells MC arranged at intersections of the plurality of word lines WL and the plurality of bit lines BL. The selection of the word line WL is performed by a row decoder 140 and the selection of the bit line BL is performed by a column decoder 145. Sense amplifiers (SA) are located for their corresponding bit lines BL and connected to at least one respective local I/O line (LIOT/B), which is in turn coupled to a respective one of at least two main I/O line pairs (MIOT/B), via transfer gates (TG), which function as switches.

The IO circuit 160 may include circuitry (not shown) that may convert read data from parallel data to serial data for providing the data to the DQ terminals. The IO circuit 160 may further include circuitry (not shown) that may convert write data received at the DQ terminals from serial data to parallel data for writing to the memory array 150. As will be described in detail herein, the IO circuit 160 may include decision feedback equalizer (DFE) circuitry 162 that may be used to analyze incoming write data. The DFE may use previous levels of the write data bits (e.g., DQ signals) stored in a buffer 164 to increase accuracy of determining the incoming bits of the write data (e.g., determining whether a write data bit is ‘0’ or ‘1’/‘low’ or ‘high’). The buffer 164 may store any number of bits. In some cases, the number of bits in the buffer 164 is specified by a standard. For example, the JEDEC DDR5 standard specifies that four bits (e.g., taps) are stored in the buffer 164.

The semiconductor device 100 may employ a plurality of external terminals that include address and command terminals coupled to command/address bus (C/A), clock terminals Clk_t and Clk_c, data terminals DQ, data strobe terminal DQS, and data mask terminal DM, power supply terminals VDD, VSS, VDDQ, and VSSQ. The external terminals may be used to communicate with an external device, such as controller 101. Controller 101 may be integrated with and/or in communication with a processor (not shown). In some embodiments, controller 101 may be included in a system on a chip (SoC).

The command/address (C/A) terminals may be supplied with an address signal from controller 101. In some embodiments, there may be fourteen C/A terminals. The address signal supplied to the address terminals are transferred, via the command/address input circuit 105, to an address decoder 110. The address decoder 110 receives the address signal and decodes the address signal to provide decoded address signal ADD. The ADD signal includes a decoded row address signal and a decoded column address signal. The decoded row address signal is provided to the row decoder 140, and a decoded column address signal is provided to the column decoder 145.

The command/address terminals may further be supplied with a command signal from the controller 101. The command signal may be provided, via the C/A bus, to the command decoder 115 via the command/address input circuit 105. The command decoder 115 decodes the command signal to generate various internal commands that include a row command signal ACT to select a word line and a column command signal Read/Write, such as a read command or a write command.

The command decoder 115 may access mode register 175 that is programmed with information for setting various modes and features of operation for the semiconductor device 100. For example, the mode register 175 may provide parameters that allow the semiconductor device 100 to operate at different frequencies, use different burst lengths, different DQS preambles/postambles, and/or other different operating conditions. In some embodiments, mode register 175 may include multiple registers.

The information in the mode register 175 may be programmed by providing the semiconductor device 100 a mode register write command, which causes the semiconductor device 100 to perform a mode register write operation. The command decoder 115 accesses the mode register 175, and based on the programmed information along with the internal command signals provides the internal signals to control the circuits of the semiconductor device 100 accordingly. Information programmed in the mode register 175 may be externally provided by the semiconductor device 100 using a mode register read command, which causes the semiconductor device 100 to access the mode register 175 and provide the programmed information (e.g., to the memory controller 101).

Turning to the explanation of the external terminals included in the semiconductor device 100, the clock terminals Clk_t and Clk_c are supplied with an external clock signal and a complementary external clock signal, respectively. As used herein, a positive clock edge refers to the point where the rising true clock signal Clk_t crosses the falling bar clock signal Clk_c, while the negative clock edge indicates that transition of the falling true clock signal Clk_t and the rising of the bar clock signal Clk_c. Commands (e.g., read command, write command, etc.) are typically entered on the positive edges of the clock signal and data is transmitted or received on both the positive and negative clock edges. The external clock signals may be provided by the controller 101. The external clock signals may be supplied to a clock input circuit 120. The clock input circuit 120 may receive the external clock signals to generate an internal clock signal ICLK. The internal clock signal ICLK is supplied to an internal clock generator 130, which may generate one or more internal clock signals for use by various components of the semiconductor device 100. For example, as shown in FIG. 1, an internal clock signal LCLK is generated based on the received internal clock signal ICLK. The internal clock signal LCLK is supplied to the command decoder 115 to control the timing of issuing commands. In another example, the internal clock signal LCLK may be provided to the IO circuit 160 to control output or input timing of data (e.g., LCLK may include the multiphase internal DQS signals). While both the command decoder 115 and IO circuit 160 are shown receiving internal clock signal LCLK, in some embodiments command decoder 115 and IO circuit 160 may receive different internal clock signals. For example, IO circuit 160 and command decoder 115 may receive clock signals having different phases and/or frequencies.

The power supply terminals are supplied with power supply potentials VDD and VSS. These power supply potentials VDD2 and VSS are supplied to an internal voltage generator circuit 170. The internal voltage generator circuit 170 generates various internal potentials such as VARY, VCCP, and the like based on the power supply potentials VDD and VSS. The internal potentials are provided merely as examples, and other or additional internal potentials may be used and/or the example potentials shown may be used for other purposes.

The power supply terminals are also supplied with power supply potentials VDDQ and VSSQ. These power supply potentials VDDQ and VSSQ are supplied to the input/output circuit 160. The power supply potentials VDDQ and VSSQ are typically the same potentials as the power supply potentials VDD2 and VSS, respectively. The dedicated power supply potentials VDDQ and VSSQ are used for the input/output circuit 160 so that power supply noise generated by the input/output circuit 160 does not propagate to the other circuit blocks. However, in other embodiments, VDD and VSS may be provided to the input/output circuit 160.

Returning to the command decoder 115, when a read command and address are issued by controller 101, read data is read from a memory cell in the memory array 150 designated by the address. The read data DQ is output to outside from the data terminals DQ, via read/write amplifiers 155 and an input/output circuit 160.

At or around when the write command and address are issued, the controller 101 may further drive an external DQS signal to the DQS terminal. In some embodiments, the external DQS signal may include a differential pair of complementary signals (e.g., DQS_t and DQS_c). Although FIG. 1 shows the DQS signal as being provided to the input/output (IO) circuit 160, in some embodiments, the DQS signal may be provided to the clock input circuit 120, which then provides an internal DQS signal to the internal clock generator 130. The internal clock generator 130 may generate a multiphase (e.g., 4-phase) internal DQS signal that is provided to the IO circuit 160.

The controller 101 provides write data is supplied to the data terminals DQ, the write data is received by data receivers in the input/output circuit 160. The data may be provided to decision feedback equalization (DFE) circuitry 162, which may include buffers for storing one or more (e.g., one, two, four) bits. DFE circuitry 162 may determine the value (e.g., logic high/low, ‘0’/‘1’), based at least in part, on the bits stored in the buffers. The data may be supplied via the input/output circuit 160 and the read/write amplifiers 155 to the memory array 150 and written in the memory cells designated by the address. When the write operation is complete, in some embodiments, the controller 101 may stop driving the external DQS signal. The external DQS signal may held high, low, or allowed to float to an indeterminate tristate condition.

As discussed previously DFE circuitry 162 maintains a “history” buffer 164 of a preceding number (e.g., 1, 2, 4) of data bits to interpret whether the current bit of write data is determined to be a logic high or a logic low (e.g., ‘1’ or ‘0’). For example, if the preceding data bits were all low, DQ data line may be at a lower voltage level and the current data bit is to be interpreted as a logical high or a low relative to that level.

However, some new write commands may have no preceding data. For any new write command where there is no preceding data, the DFE circuitry 162 may be expected to have been placed into a reset condition such that the buffer 164 has a known state. That is, the bits in the buffer 164 are set to pre-determined values (e.g., all high, all low, etc.). The controller 101 may set the signals provided to the DQ terminals to be at the desired voltage level, such as high at the positive rail, in order to correspond to the known state for the buffer and/or the bits in the buffer 164 may be set independently by the semiconductor device 100.

In some embodiments, the controller 101 may have a preamble period where the external DQS signal is driven by the controller 101 before the first bit of write data is provided to allow time for enabling the write circuitry prior to providing the first bit of write data. Similarly, the controller 101 may have a postamble period where the external DQS signal is still driven by the controller 101 after the last write data bit to allow time for disabling of write circuitry before the controller 101 ceases to drive the external DQS signal. In some embodiments, the preamble period and/or postamble period may be selected using mode register 175. In some embodiments, the permitted preamble and postamble periods may be defined by a standard, such as the JEDEC DDR5 standard.

In some embodiments, write operations are performed consecutively such that data entry is gapless between two consecutive writes. In this case, the postamble for the first write operation and/or the preamble for the second write operation may be completely eliminated. For some consecutive write operations, there may be clock cycle gaps having a certain gap (e.g., 1, 2, 3, or more cycles) between the data burst of the first write operation and the data burst of the second write operation.

In some consecutive write operations, the spacing between the first write operation and the second write operation is such that the entire first postamble and second preamble is met and there may even be additional clock cycles in between the two write operations. When there are additional clock cycles in between the first postamble and second preamble, the DQS signal may be disabled or driven depending on the specification of the device.

Internally, the DFE circuitry 162 may capture data received on the DQ pads responsive, at least in part, to a gated internal DQS signal (which is generated based on the externally received DQS signal). For example, the DFE circuitry 162 may capture data received on the DQ pads responsive to the rising and falling edges of the driving signals of the DQ pads (which may be generated responsive to the internal DQS signal) and store the captured bits in the DFE buffer. A “gating event” is an event (e.g., a change in a state of one or more signals) that causes the enabling or disabling of passing the gated internal DQS signal to one or more components of the semiconductor device 100, such as the DFE circuitry 162. A gating event may cause an “erasure” of a pulse of the DQS signal. That is, the gated internal DQS signal provided to other internal device components (e.g., DQ drivers) may be “missing” a pulse compared to the ungated DQS signal.

At the end of a write burst, the internal DQS signal may be disabled (e.g., prevented from being received by other components) due to a gating event and/or disabling of the external DQS signal. During the disabling of internal DQS signal, the DFE circuitry 162 may reset the DFE buffer 164 responsive to a reset signal. After the internal DQS is enabled (e.g., allowed to be received by the other components), the DFE circuitry 162 may resume capturing data from the DQ pads and storing the captured bits in the buffer 164. However, as noted previously, if the DFE circuitry 162 resumes capturing data before the reset of the buffer 164 is complete, it could change the phase of the bits in the buffer 164 and result in reduced accuracy interpreting the data.

According to embodiments of the present disclosure, one or more internal signals may be used to trigger a gating event and cause the gating event to occur within a desired time window. This may result in one or more pulses of the DQS signal being “erased” from the internal DQS signal. Erasure of the pulse of the DQS signal may increase the gap “seen” internally in the driven DQS signal. In some cases, such as when there is a one system clock cycle (1 CLK) gap in the external DQS signal, this may result in an internal gap of two system clock cycles (2 CLK). The increase in the internal gap delays resumption of the DFE circuitry 162 capturing data from the DQ terminals. This may reduce or eliminate the risk of the DFE buffer 164 not being completely reset prior to resuming data collection.

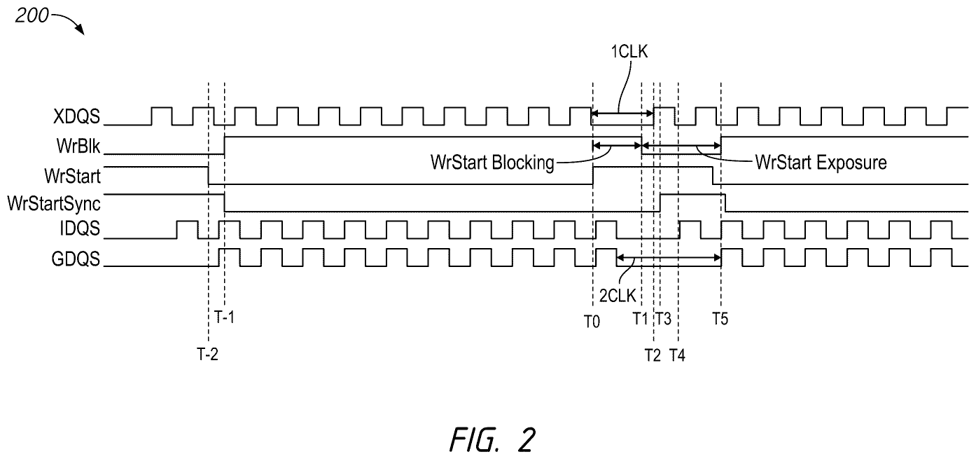

FIG. 2 is a timing diagram illustrating various signals of a semiconductor device according to at least one embodiment of the disclosure. Timing diagram 200 illustrates various signals received and generated by a memory (e.g., memory device) of semiconductor device, such as semiconductor device 100 shown in FIG. 1. Timing diagram 200 illustrates various signals generated responsive to two consecutive write commands.

The top line of timing diagram 200 illustrates a data strobe (DQS) signal provided to an external DQS terminal of the memory device (XDQS) by a controller. The bottom two lines illustrate DQS signals internal to the memory device. IDQS is an internal DQS signal generated responsive to the XDQS signal. GDQS is a gated version of the IDQS signal. The GDQS signal may be provided to various components of the memory device such as DFE circuitry (e.g., DFE circuitry 162), drivers for the DQ terminals, and/or other components. The middle lines of timing diagram 200 illustrate signals associated with a write start signal. The write start signal (WrStart) begins the internal write operation of the memory device. The write start signal may be generated responsive to receipt of a write command from a controller.

Prior to time T0, the memory device began executing a first write command. At the end of the write burst (and postamble, if applicable), the controller stops driving the XDQS signal at or around time T0. Due to propagation delays through the memory device, the IDQS signal and GDQS signal have a pulse after T0. A write end signal (not shown in FIG. 2) may cause a gating event that disables GDQS (e.g., prevents IDQS from being passed) after the pulse on GDQS that occurs at or just after T0. The DFE circuitry may begin a reset operation of the buffer upon or after disablement of the GDQS.

The WrStart signal may go high at or around T0 for a second consecutive write command. The controller may resume driving the XDQS signal for execution of the second write command at or around time T2. A WrStart signal may cause another gating event, which would re-enable GDQS (e.g., allows IDQS to be passed). However, if the WrStart signal is provided to the gating circuitry too soon (e.g., prior to the end of the last pulse as shown in the example in FIG. 2), GDQS will be re-enabled before the DFE circuitry has finished resetting the buffer.

Some existing memories include circuitry to determine that a pre-amble low time is violated based on a write-to-write time being below a given threshold (e.g., a gap below number of system clock cycles). These memories may prevent a re-gating sequence caused by WrStart and/or other signal all together. These memories induce a non-interrupted XDQS to GDQS transfer, and the XDQS CLK gap would be present in the GDQS signal. These memories may suppress resetting of DFE buffer or risk incomplete resetting of the DFE buffer. However, suppression of resetting the DFE buffer or incomplete resetting of the DFE may reduce accuracy of the DFE circuitry. For example, a phase shift in the data in the buffer may occur as discussed previously, and/or bits may be “lost” by the buffer. By lost, it means that bits are provided on the DQ terminals, but are not captured by the buffer. Thus, reflections from the lost bits may be present, but may not be properly compensated for because these bits are not stored in the buffer.

According to embodiments of the present disclosure, a gating event is permitted to occur responsive to the WrStart signal (and/or a signal based on the WrStart signal). However, to prevent premature enablement of the GDQS, the WrStart signal is selectively blocked (and/or gated) from being provided to the gating circuitry of GDQS (and/or the circuitry providing signals to the gating circuitry of GDQS). The selectively provided write start signal may be referred to as a write start synchronization signal (WrStartSync). The WrStartSync may be different from WrStart in that it may change states at a different time compared to WrStart and/or may be a different duration (e.g., shorter) than WrStart. A write block (WrBlk) signal is used to block WrStart from triggering a gating event. As shown in FIG. 2, the WrBlk signal goes high at time T−1, shortly after the WrStart signal goes low at T−2 (as part of the write operation associated with the first write command). While high, the WrBlk signal blocks WrStart signal. At T1, the WrBlk signal goes low. WrBlk may go low responsive to another signal such as a write end signal or a write end reset signal. When WrBlk is low, WrStart may be allowed to pass to the gating circuitry of GDQS as WrStartSync.

WrStart Sync goes high at time T2 responsive to WrBlk going low and WrStart being high. A gating event occurs, which causes an “erasure” of an IDQS pulse from the enabled/passed GDQS signal. Thus, the pulse of IDQS at or around time T4 is not present in the GDQS signal, and GDQS does not have a pulse until at or around time T5. In other words, a first pulse of GDQS is later in time compared to IDQS. Accordingly, the 1CLK gap in the XDQS signal is a 2CLK gap in the GDQS signal. The buffer of the DFE circuit has completed its reset, and may begin storing bits around or after time T5. Because the buffer finished resetting, the accuracy of the DFE circuit may not be affected by the 1CLK XDQS gap.

As noted previously, some of the pulses of the DQS signals may be associated with preamble or postamble cycles rather than write data. In some cases, such as a 0.5 CLK preamble standard setting may be “violated” by the GDQS signal. However, the standard does not set specific requirements on how preamble and postamble pulses are handled internally by the memory devices. The preamble, postamble, and burst lengths are known based on information stored in the mode register and/or provided with the write command. Accordingly, even if a preamble or postamble pulse is eliminated or WrStart ends up completely blocked, GDQS can be locally enabled based on existing write gap signaling in the memory device.

Various signals and circuitry can be used to implement WrBlk and WrStartSync. In some embodiments, existing signals may be used to implement WrBlk and/or WrStartSync. Different example embodiments implementing a gating event of the internal DQS signal to increase the internal gap of the DQS signal will be provided herein. However, the specific signals and circuits used are provided merely as examples, and the principles of the present disclosure are not limited to the specific embodiments shown. For example, while the embodiments shown utilize the internal per device addressing (PDA) signal, other existing signals or a new signal may be provided. Further, variations of gating circuitry and signal delay circuitry shown herein would be readily apparent to those with skill in the art.

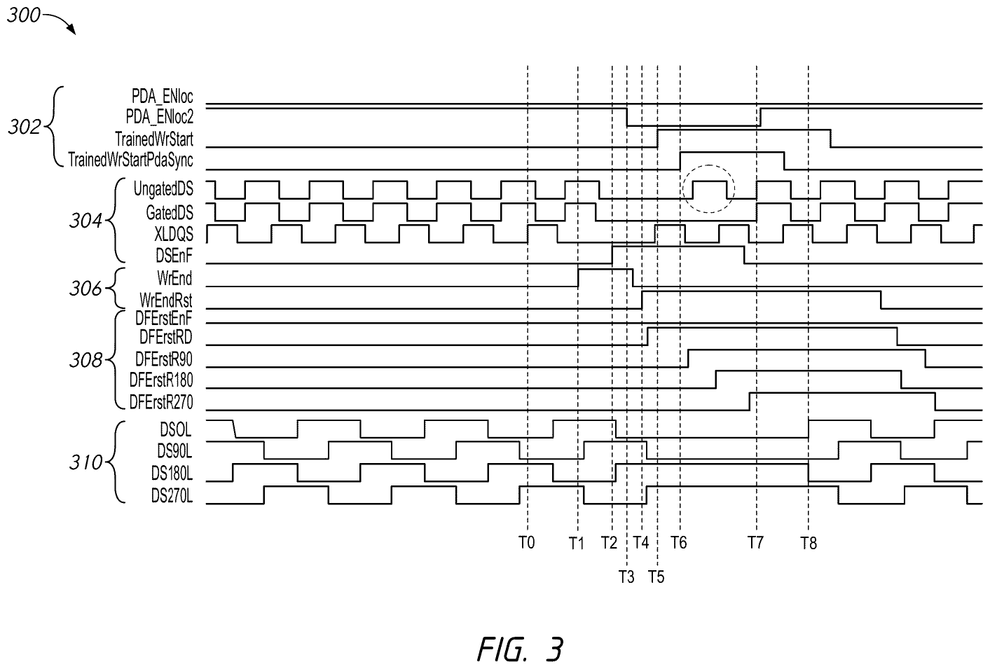

FIG. 3 is a timing diagram illustrating various signals of a semiconductor device according to at least one embodiment of the disclosure. Timing diagram 300 illustrates various signals received and generated by a memory (e.g., memory device) of semiconductor device, such as semiconductor device 100 shown in FIG. 1. Timing diagram 300 illustrates various signals generated responsive to two consecutive write commands.

Top portion 302 illustrates signals related to per device addressing (PDA) capabilities of a semiconductor device and write start signals. Typically, PDA signals are used during a PDA mode where a controller can assign addresses to one or more devices of a system. The state of PDA_ENloc may be based on whether the memory device is in PDA mode. The mode may be set based on one or more commands and/or signals provided by a controller and/or one or more settings in a mode register. The PDA_ENloc2 may be based, at least in part, on the PDA_ENloc signal. As explained herein, PDA signal PDA_ENloc2 is used to provide timing control for a gating event for an internal gated DSQ signal. For example, PDA_ENloc2 may be used to implement WrBlk shown in FIG. 2. The operating mode where read and write commands are executed and the PDA mode are mutually exclusive. Accordingly, use of PDA_ENloc2 according to principles of the present disclosure does not conflict with the “original intended use” of the PDA signals.

TrainedWrStart is a signal generated based, at least in part, on a write start signal WrStart (not shown in FIG. 3) and training performed (e.g., during an initialization phase of the device). TrainedWrStart may be adjusted in time and/or duration compared to WrStart based on propagation delays, process variations, and/or other factors. TrainedWrStartPdaSync is a signal based at least in part on PDA_ENloc2. As described herein, TrainedWrStartPdaSync may implement WrStartSync shown in FIG. 2.

Portion 304 illustrates signals related to the data strobe signals. UngatedDS is an internal DQS signal (e.g., IDQS shown in FIG. 2), and GatedDS is the UngatedDS signal selectively provided to one or more components of the device, such as DFE circuitry 162 (e.g., GDQS shown in FIG. 2). XLDQS is an external DQS signal provided by a controller to the device (e.g., XDQS in FIG. 2). DQS enable signal (false) DSEnF is a signal for enabling and disabling internal DQS signals. In particular, DQSEnF enables and disables the multi-phase DQS signals in bottom portion 310. DS0L, DS90L, DS180L, and DS270L are four signals for driving receipt of read data from the DQ terminals. The signals in portion 310 are each offset in phase by 90-degrees from two of the other signals in portion 310. DS0L, DS90L, DS180L, and DS270L may be enabled when DSEnF is low.

Portion 306 illustrates signals related to the write end signal. As discussed, the write end signal (WrEnd) indicates the end of a write operation performed responsive to a write command. The write end reset (WrEndRst) signal is used to reset or set the state of various signals responsive to the WrEnd signal.

Portion 308 illustrates signals related to resetting the buffer of DFE circuitry, such as buffer 164 of DFE circuitry 162 shown in FIG. 1. DFErstEnF may enable resetting of the buffer of the DFE circuitry when low. DFErstR0, DFErstR90, DFErstR180, and DFErstR270 are signals used to generate reset pulses that reset bits in the DFE buffer. In some embodiments, each signal may reset a different bit in the DFE buffer.

Sometime before T0, the memory device received a first write command and began performing a write operation. At T0, a final pulse of the XLDQS is provided by the controller. The final pulse may correspond to a final data bit or a final postamble bit. Responsive, at least in part, to the final XLDQS pulse (and/or the resulting final internal DQS pulse), a pulse of the WrEnd signal is generated by the memory device at or around time T1. Responsive, at least in part, to the WrEnd pulse, the WrEndRst signal may transition to a high state at or around time T4. At or around time T2, DSEnF may transition high, disabling the DS0L, DS90L, DS180L, and DS270L signals. In some embodiments, DSEnF may transition responsive, at least in part, to the WrEnd pulse. Also responsive to the WrEnd pulse and/or WrEndRst signal, PDA_Enloc2 may transition to a low (non-blocking) state.

At some point in time prior to T5, the memory device received a second write command. Responsive to the second write command, a TrainedWrStart signal is transitioned to a high state at or around time T5, and the controller begins driving the XLDQS signal again. Because PDA_Enloc2 is high, TrainedWrStartPdaSync is permitted to pass to the gating circuitry of the GatedDS signal. A gating event occurs, and the GatedDS signal is driven at or around time T7. Similar to FIG. 2, a pulse in UngatedDS (circled in FIG. 3) is erased from the GatedDS signal.

As shown in FIG. 3, the pre-existing PDA signals may be utilized as a “hook” to act as a blocking signal for write start signals. This may help ensure that write start signals are not passed to the gating circuitry of the GatedDS signal too early. When the write start signals are prevented from arriving too early (e.g., before the end of the last UngatedDS pulse), this may facilitate the re-gating event that prevents a first pulse of the UngatedDS signal from appearing in the GatedDS signal. This allows the increase in the internal gap of the DQS signal, which may allow for proper resetting of the DFE buffer.

Turning to the DFE reset signals, as noted, the WrEndRst transitions to high, and the WrEnd pulse ends at or around time T4. Responsive, at least in part, to WrEndRst and/or WrEnd, The DFE buffer reset signals DFErstR0, DFErstR90, DFErstR180, and DFErstR270 transition high beginning between times T4 and T5 and ending at or around time T7. The bits in the DFE buffer may be reset responsive to the rising edges of the DFE buffer reset signals. Accordingly, because the first pulse in the GatedDS signal does not occur until at or around T7, all of the bits of the buffer are able to be reset before the DFE circuitry begins capturing bits from the DQ terminals. In the example shown in FIG. 3, this may occur at or around time T8, where DS0L and DS180 transition as the signals in portion 310 begin driving again responsive, at least in part, to the GatedDS signal.

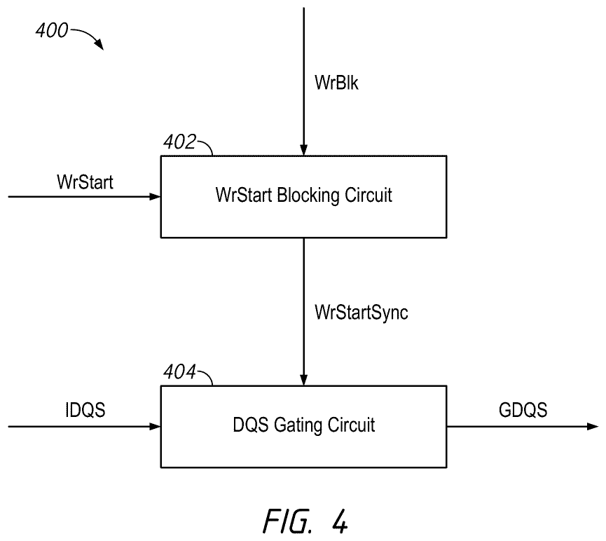

FIG. 4 is a block diagram of circuitry included in a semiconductor device according to at least one embodiment of the disclosure. The circuitry 400 shown in FIG. 4 may be included in semiconductor device 100 in some embodiments. The circuitry 400 may include a write start (WrStart) signal blocking circuit 402 and a DQS gating circuit 404.

The WrStart blocking circuit 402 may receive a write start signal WrStart. As discussed with reference to FIG. 2, the WrStart signal may have a state based on whether a memory device, such as a memory device included in semiconductor device 100, has received a write command (e.g., from a controller). In some memory devices, the WrStart signal may be provided to several components internal to the memory device. According to embodiments of the present disclosure, at least some components do not receive WrStart, but a blocked and/or gated version of WrStart. As illustrated in FIG. 4, the WrStart blocking circuit 402 may selectively block and/or gate the WrStart signal based on a state of a write block signal (WrBlk) and provide a WrStartSync signal. As shown in the example in FIG. 3, WrBlk may be based on one or more other signals in the memory (e.g., PDA_ENloc WrEnd, and/or WrEndRst). When WrBlk is in one state, the WrStart blocking circuit 402 may block the WrStart signal from passing (e.g., hold WrStartSync low even if WrStart is high), and allow the WrStart signal to pass as WrStartSync when WrBlk is in another state.

The DQS gating circuit 404 may gate an internal DQS signal (IDQS) based, at least in part, on the WrStartSync signal and provide a gated DQS signal (GDQS). The WrStartSync changing states may trigger a gating event in the DQS gating circuit 404. The gated GDQS signal may be provided to various other components of the memory device (not shown in FIG. 4), such as DQ terminal drivers. As discussed with reference to FIGS. 2 and 3, providing DQS gating circuit with WrStartSync instead of WrStart may increase an internal gap in the DQS signal, which may prevent DFE circuit from capturing data from the DQ terminals prior to completion of resetting the DFE buffer.

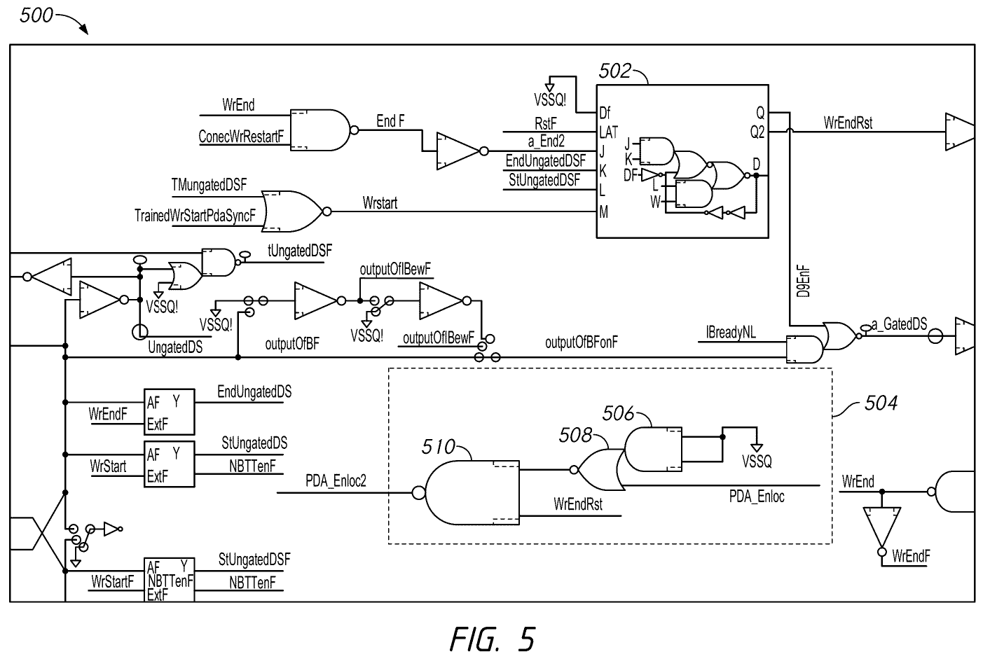

FIG. 5 is a circuit diagram of a portion of a data path included in a semiconductor device according to at least one embodiment of the disclosure. The data path 500 shown in FIG. 5 may be included in semiconductor device 100 in some embodiments. While data path 500 shows several components, many of these are known in the art and/or are described in other applications, such as U.S. Patent Application No. 63/637,733. Accordingly, only those features related to embodiments of the present disclosure will be discussed.

Logic circuit 504 is an example of a circuit that may be used to generate the PDA_Enloc2 signal as discussed with reference to FIG. 3, which may be used to implement the WrBlk signal shown in FIGS. 2 and 4. An AND logic circuit 506 may have two inputs coupled to VSSQ and provide an output to NOR logic circuit 508. The NOR logic circuit 508 may receive the PDA_ENloc signal as another input. The NOR logic circuit 508 may provide an output to NAND logic circuit 510. A latch 502 receives various signals based on write end, write start, and data strobe signals. The latch 502 outputs a data strobe signal enable (active low) and a write end restart signal (WrEndRst). The WrEndRst is provided as another input to NAND logic circuit 510. The NAND logic circuit 510 may provide PDA_ENloc2 as an output, which may be used to block WrStart and generate a WrStartPdaSync signal as shown in FIG. 3.

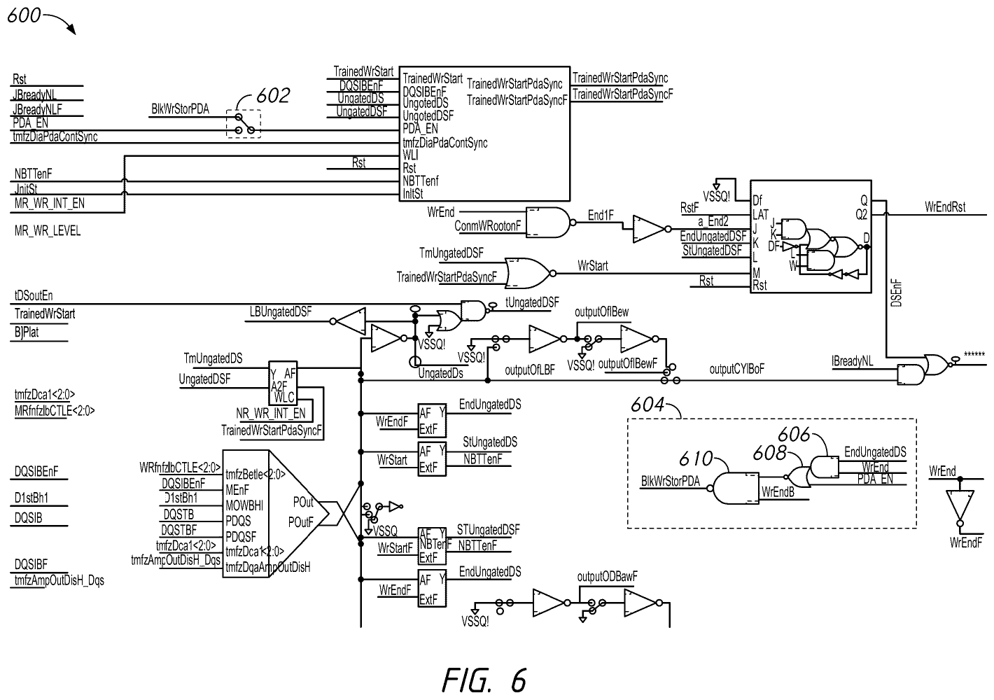

FIG. 6 is a circuit diagram of a portion of a data path included in a semiconductor device according to at least one embodiment of the disclosure. The data path 600 shown in FIG. 6 may be included in semiconductor device 100 in some embodiments. While data path 600 shows several components, many of these are known in the art and/or are described in other applications, such as U.S. Patent Application No. 63/637,733. Accordingly, only those features related to embodiments of the present disclosure will be discussed.

Logic circuit 604 is an example of a circuit that may be used to generate the BlockWrStOrPDA signal, which may be used to implement the WrBlk signal shown in FIGS. 2 and 4. An AND logic circuit 606 may receive an EndUngatedDS signal, write end (WrEnd) as inputs and provide an output to NOR logic circuit 608. The NOR logic circuit 608 may receive the PDA_EN signal as another input. The NOR logic circuit 608 may provide an output to NAND logic circuit 610. The NAND logic circuit 610 may also receive a WrEndB signal as an input. The WrEndB may be based, at least in part, on the WrEnd signal. The NAND logic circuit 610 may provide BlockWrStOrPDA as an output, which may be used to block WrStart and generate a WrStartPdaSync signal as shown in FIG. 3. The BlockWrStOrPDA may be provided to a switch 602, which may allow either PDA_En or BlockWrStOrPDA to be provided to various circuits. This may facilitate use of the PDA_En signal during PDA mode of the memory device in some embodiments.

The circuits shown in FIGS. 5 and 6 are provided merely as examples, and embodiments are not limited to these specific circuits. Other circuits may be used for providing an increased gap in the internal DQS signal without departing from the principles of the present disclosure.

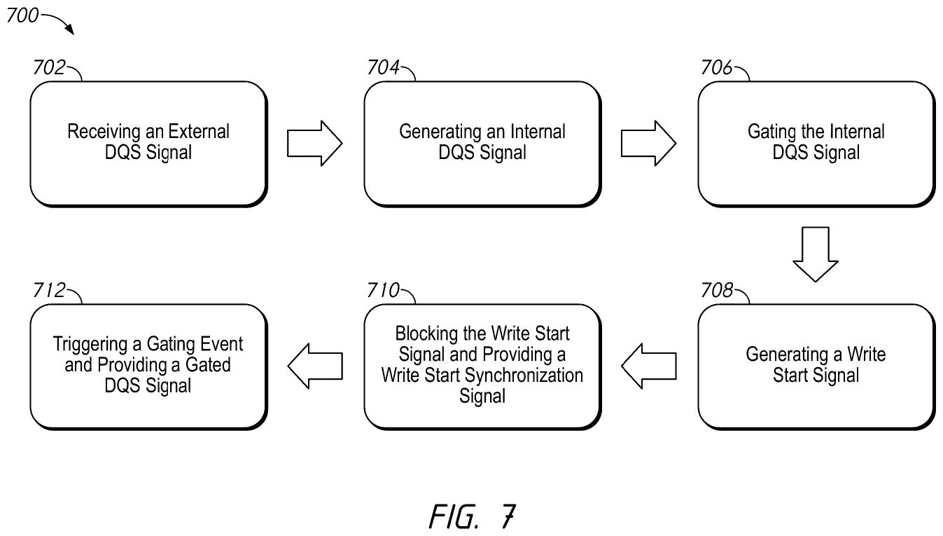

FIG. 7 is a flow chart of a method according to at least one embodiment of the present disclosure. The method 700 may be performed in whole or in part by a semiconductor device, such as semiconductor device 100, in some embodiments.

At block 702, “receiving an external data strobe (DQS) signal” may be performed. In some embodiments, the external DQS signal may be received at a memory device, such as a memory device included with semiconductor device 100. The external DQS signal may be provided by a processor or controller, such as controller 101.

At block 704, “generating an internal DQS signal” may be performed. The internal DQS signal may be generated by the memory device based on the external DQS signal in some embodiments.

At block 706, “gating the internal DQS signal” may be performed. The gating may be performed by a gating circuit, such as DQS gating circuit 404 in FIG. 4.

At block 708, “generating a write start signal” may be performed. In some embodiments, the write start signal may be an internal signal generated by the memory device responsive to a write command, such as a write command received from a controller.

At block 710, “blocking the write start signal and providing a write start synchronization signal” may be performed by the memory device. The blocking may be responsive to a blocking signal, such as WrBlk shown in FIGS. 2 and 4 or PDA_Enloc2 as shown in FIG. 3 in some embodiments. In some embodiments, the blocking signal is based, at least in part, on a per device address signal

At block 712, “triggering a gating event and providing a gated DQS signal” may be performed by the memory device. In some embodiments, the triggering may be responsive to a first state of the write start synchronization signal based on the write start signal. For example, WrStartSync transitioning to a high state causes a gating event as described with reference to FIGS. 2 and 3. In some embodiments, a first pulse of the gated DQS signal is later in time compared to a first pulse of the internal DQS signal. In some embodiments, this may be due to “erasure” of one of the internal DQS pulses by the gating event. Thus, in some embodiments, the gated DQS signal has one less pulse than the internal DQS signal. In some embodiments, changing a state of a write end signal, a write end reset signal, or a combination thereof, may be performed, and changing the state of the write start synchronization signal to the first state is performed responsive, at least in part, to the changing state(s) of one or more of these signals.

The method 700 may result in a longer gap in the gated DQS signal compared to the external DQS signal. This may allow sufficient time for a reset of a buffer of a DFE circuit (such a buffer 164 of DFE circuitry 162). For example, a 2 CLK gap may be sufficient to allow a reset of all four bits in a DFE buffer in some embodiments.

The techniques disclosed herein may allow for an external 1CLK DQS gap appear as a 2CLK DQS gap internally. This may increase the timing margin for resetting the DFE buffer by a full clock cycle, which may reduce the risk of the DFE buffer not being fully reset between consecutive write operations.

From the foregoing it will be appreciated that, although specific embodiments of the disclosure have been described herein for purposes of illustration, various modifications may be made without deviating from the spirit and scope of the disclosure. Accordingly, the disclosure is not limited except as by the appended claims.

What is claimed is:

1. A memory device comprising:
an external terminal configured to receive an external data strobe (DQS) signal;
a gating circuit configured to receive an internal DQS signal based on the external DQS signal and selectively provide a gated DQS signal; and
a blocking circuit configured to receive a write start signal and provide a write start synchronization signal based on the write start signal to the gating circuit, wherein a gap in driving of the gated DQS signal is greater than a gap in driving of the external DQS signal.

2. The memory device of claim 1, wherein a state of the write start synchronization signal is based on a state of a blocking signal received by the blocking circuit.

3. The memory device of claim 2, wherein the blocking signal is based, at least in part, on a write end signal, a write end reset signal, or a combination thereof.

4. The memory device of claim 2, wherein the blocking signal is further based, at least in part, on a per device address signal.

5. The memory device of claim 1, wherein the gap in driving of the external DQS signal is one clock cycle of a system clock signal received by the memory device and the gap in driving of the gated DQS signal is two clock cycles of the system clock signal.

6. The memory device of claim 1, further comprising a decision feedback equalizer (DFE) circuit configured to capture data at one or more data terminals and store one or more captured data bits in a buffer.

7. The memory device of claim 6, wherein the buffer of the DFE circuit is configured to be reset after a first write operation and before a second write operation.

8. The memory device of claim 1, wherein the memory device comprises a DDR5 DRAM device.

9. A method comprising:
receiving an external data strobe (DQS) signal at a memory device;
generating an internal DQS signal with the memory device based on the external DQS signal;
gating the internal DQS signal;
generating a write start signal in the memory device;
blocking, responsive to a blocking signal, the write start signal and providing a write start synchronization signal; and
responsive to a first state of the write start synchronization signal based on the write start signal, triggering a gating event and providing a gated DQS signal, wherein a first pulse of the gated DQS signal is later in time compared to a first pulse of the internal DQS signal.

10. The method of claim 9, wherein the gated DQS signal has one less pulse than the internal DQS signal.

11. The method of claim 9, further comprising changing a state of a write end signal, a write end reset signal, or a combination thereof, and changing a state of the write start synchronization signal to the first state responsive, at least in part, to the changing state.

12. The method of claim 9, further comprising receiving a system clock signal at the memory device, wherein when the external DQS signal is not driven for one cycle of the system clock signal, the gated DQS signal is not driven for two cycles of the system clock signal.

13. The method of claim 12, further comprising resetting a buffer of a data equalization circuit within two cycles of the system clock signal.

14. The method of claim 12, wherein when the write start synchronization signal is in a second state, no gating event is triggered responsive to the write start signal.

15. The method of claim 9, further comprising:
receiving a first write command;
receiving a second write command, wherein the write start command is generated responsive to the second write command;
receiving a gap in the external DQS signal between the first write command and the second write command, wherein the gap ends responsive to the second write command;
generating a gap in the internal DQS signal responsive to the gap in the external DQS signal; and
generating a gap in the gated DQS signal responsive, at least in part, to the gap in the internal DQS signal, wherein the gap in the gated DQS signal is greater than the gap in the external DQS signal.

16. The method of claim 15, further comprising changing a state of the blocking signal responsive, at least in part, to a last pulse of the external DQS signal before the gap, wherein changing the state of the blocking signal transitions the write start synchronization signal to the first state.

17. The method of claim 15, further comprising resetting a buffer of a data equalization circuit, at least in part, during the gap in the gated DQS signal.

18. The method of claim 9, wherein at least one pulse of the external DQS signal is a preamble pulse and at least one pulse of the external DQS signal is a postamble pulse.

19. The method of claim 18, wherein a number of pulses of the external DQS signal that are preamble pulses or postamble pulses are defined in a standard.

20. The method of claim 9, wherein the blocking signal is based, at least in part, on a per device address signal.
